(19) United States
(12) Patent Application Publication
(10) Pub. No.: US 2024/0314942 A1
(43) Pub. Date: Sep. 19, 2024

(54) CIRCUIT BOARD LAYER BUILD-UP PROCESS WITH ENHANCED POSITIONING PRECISION

(71) Applicant: Hui-ju Lee, New Taipei City (TW)

(72) Inventor: Chia-Ming LI, New Taipei City (TW)

(21) Appl. No.: 18/588,488

(22) Filed: Feb. 27, 2024

(30) Foreign Application Priority Data
Mar. 16, 2023 (TW) 112109840

(51) Int. Cl. H05K 3/46; H05K 3/32; H05K 3/42

(52) U.S. Cl. CPC H05K 3/4682; H05K 3/321; H05K 3/423; H05K 2201/0355; H05K 2203/0195; H05K 2203/085

(57) ABSTRACT

A circuit board layer build-up process with enhanced positioning precision is provided. The circuit board layer build-up process is advantageous in that regardless of the number of times for which the circuit board layer build-up process has been performed in a row, all the newly added layers are formed with target windows (including copper foil target windows and insulating adhesive target windows) each having a larger contour than the corresponding positioning target through hole. During the via forming process and the subsequent patterning process, therefore, machine vision-based positioning can always be carried out using the positioning target through holes in the substrate layer as positioning reference points, thereby preventing layer errors and increasing the precision and yield of circuit boards.

### BACKGROUND OF THE INVENTION

### 1. Technical Field

The present invention relates to a layer build-up process for a circuit board and more particularly to a circuit board layer build-up process that can prevent layer errors.

### 2. Description of Related Art

The manufacturing process of a circuit board includes drilling a plurality of positioning holes in the circuit board so that the position of the circuit board can be determined by machine vision to ensure the precision of vias and circuit patterns. “Layer errors”, however, have long been a problem of the conventional positioning holes because of the multiple times for which a layer build-up process is performed in a circuit board manufacturing process. Each time the layer build-up process is completed, the top layer is drilled with positioning holes, and yet the mechanical tolerances of the drilling equipment and of the X-ray positioning equipment make it inevitable that the top-layer positioning holes are not perfectly aligned with the positioning holes in the previous layer. In other words, the “layer errors” of positioning holes occur because the existing techniques cannot ensure that the positioning holes in different layers are free of positional errors. If the positioning holes themselves, which are intended for machine vision-based positioning, have errors, the vias and circuit patterns that are formed with reference to the positioning holes must have errors too, and the more the circuit board layers, the greater the accumulated errors. The layer error problem of the existing techniques has had a negative impact on the precision and yield of the manufacturing processes of circuit boards.

### BRIEF SUMMARY OF THE INVENTION

In view of the above, the primary objective of the present invention is to provide a circuit board layer build-up process that can prevent layer errors.

To achieve the aforesaid objective, the present invention provides a circuit board layer build-up process that has enhanced positioning precision, and the layer build-up process includes the following steps:
step 1: providing a semi-finished circuit board, wherein the semi-finished circuit board includes a substrate layer and a substrate circuit layer, the substrate circuit layer is formed on the substrate layer, and the substrate layer has a plurality of positioning target through holes;
step 2: adhesively attaching a self-adhesive copper foil to the semi-finished circuit board by vacuum pressing, wherein the self-adhesive copper foil is in a wound state in the first place and has a copper foil layer and an insulating adhesive layer, the insulating adhesive layer is applied over the copper foil layer, and the substrate circuit layer is in contact with the insulating adhesive layer but not in contact with the copper foil layer;
step 3: forming a plurality of copper foil target windows in the copper foil layer, wherein the copper foil target windows correspond to the positioning target through holes respectively in a thickness direction, and each of the copper foil target windows has a larger contour than the corresponding positioning target through hole;
step 4: removing those portions of the insulating adhesive layer that correspond to the copper foil target windows respectively in the thickness direction, thereby forming a plurality of insulating adhesive target windows that correspond to the positioning target through holes respectively in the thickness direction, wherein each of the insulating adhesive target windows has a larger contour than the corresponding positioning target through hole; and
step 5: performing a first positioning operation on the semi-finished circuit board, with at least some of the positioning target through holes used as the positioning reference points in a machine vision image, forming a plurality of windows in the copper foil layer after the first positioning operation, and forming a plurality of vias by removing those portions of the insulating adhesive layer that correspond to the windows respectively in the thickness direction.

The present invention is advantageous in that regardless of the number of times for which the layer build-up process has been performed successively, all the newly added layers are formed with target windows (including copper foil target windows and insulating adhesive target windows) that each have a larger contour than the corresponding positioning target through hole. This allows the positioning target through holes in the substrate layer to be used as positioning reference points when machine vision-based positioning is performed for the via forming process and for the subsequent patterning process, thereby preventing layer errors and hence increasing the precision and yield of circuit boards.

### BRIEF DESCRIPTION OF THE SEVERAL VIEWS OF THE DRAWINGS

FIG. 1, FIG. 2, and FIG. 5 to FIG. 12 schematically show the process according to a first embodiment of the present invention.

FIG. 3 is a schematic drawing of a vacuum pressing machine.

FIG. 4 is a sectional view of a self-adhesive copper foil.

### DETAILED DESCRIPTION OF THE INVENTION

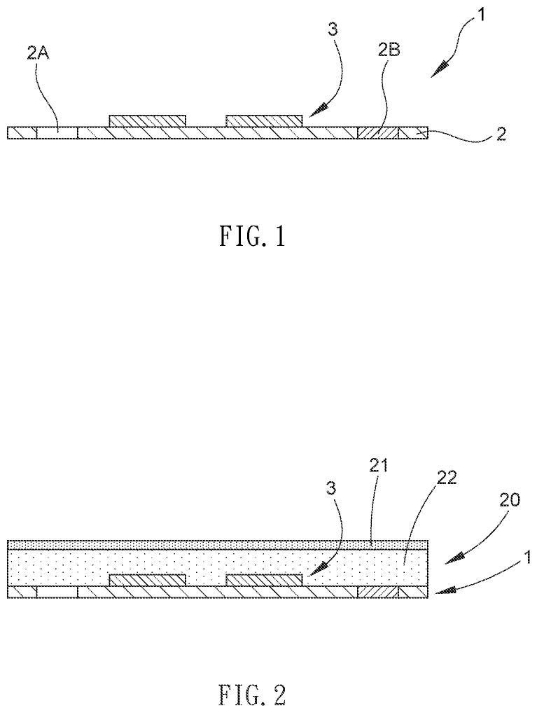

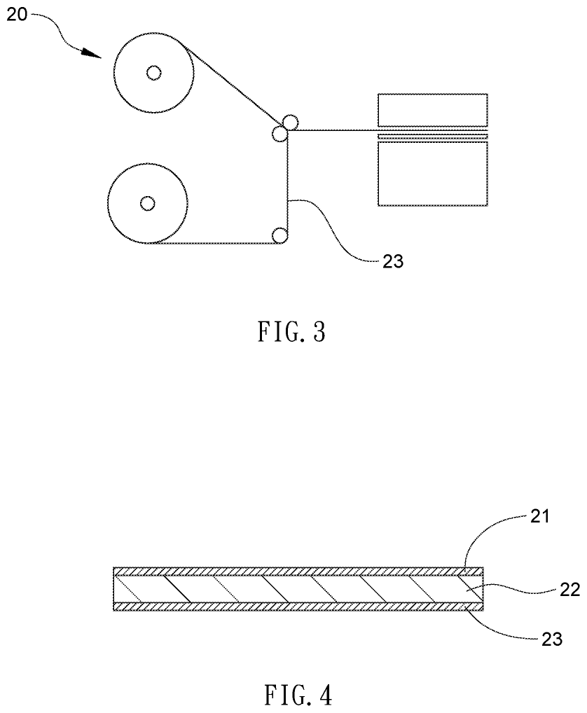

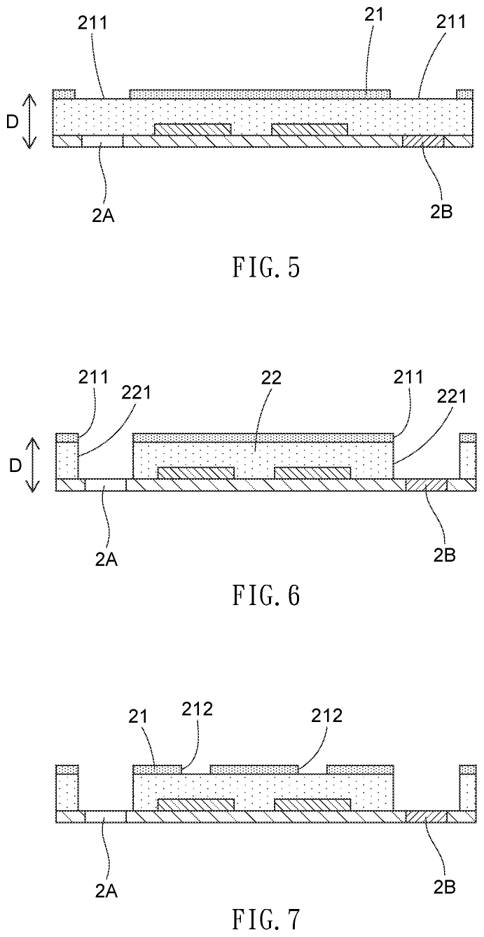

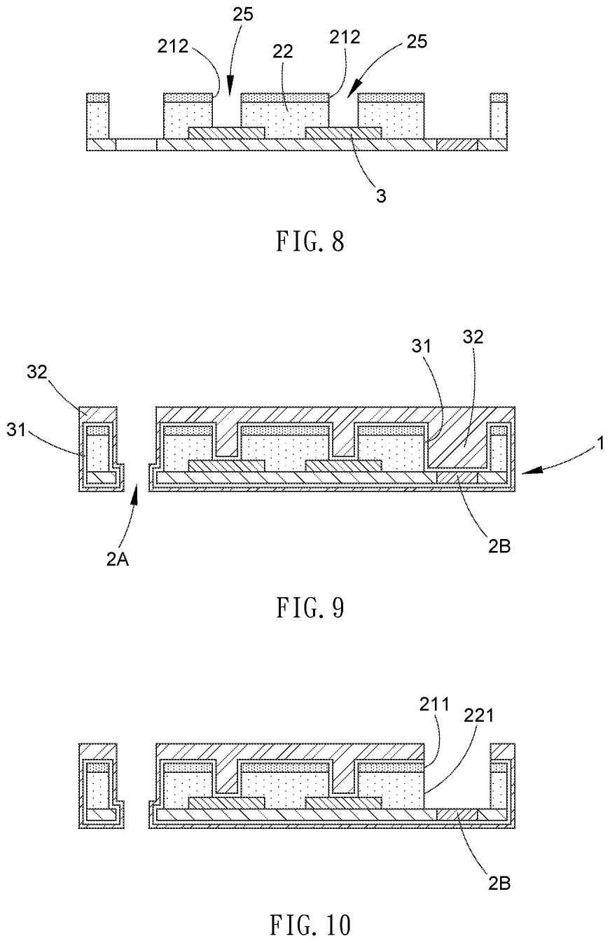

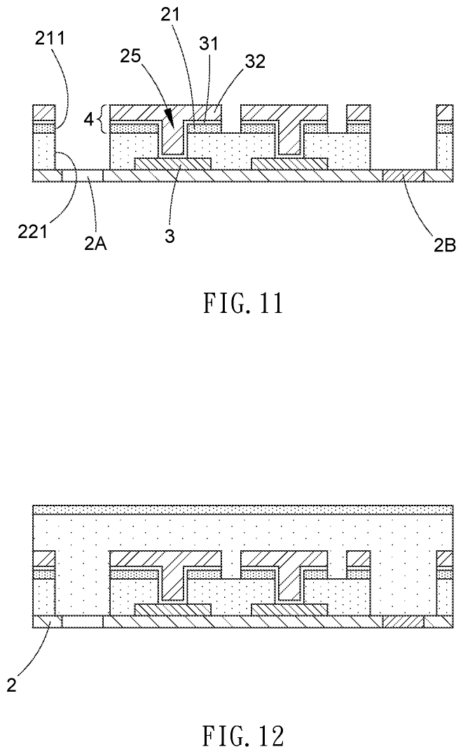

The circuit board layer build-up process according to a first embodiment of the present invention is described below with reference to FIG. 1, FIG. 2, and FIG. 5 to FIG. 12. It is well known in the art that a circuit board generally has a plurality of circuit layers, that each two adjacent circuit layers are separated by a dielectric layer, that each dielectric layer is formed with a plurality of vias, and that the wall of each via is plated with copper to electrically connect the adjacent circuit layers. The layer build-up process is a process for forming a new circuit layer and a new dielectric layer on a semi-finished circuit board and includes the following steps:
Step 1: A semi-finished circuit board 1 is provided as shown in FIG. 1. The semi-finished circuit board 1 includes a substrate layer 2 and a substrate circuit layer 3. The substrate layer 2 is, for example but not limited to, an FR-4 substrate. The substrate circuit layer 3 is a patterned layer of electrically conductive material (e.g., copper) formed on the substrate layer 2. The substrate circuit layer 3 can be formed by any conventional patterning method used in a circuit board manufacturing process. What is different from the prior art is that the substrate layer 2 has a plurality of positioning target through holes 2A and 2B. The positioning target through holes 2A are hollow and therefore can be understood as “through hole targets”. The positioning target through holes 2B, on the other hand, are completely filled with resin and therefore can be understood as “resin targets”. In this embodiment, some of the positioning target through holes, i.e., the positioning target through holes 2A, are through hole targets, and the other positioning target through holes, i.e., the positioning target through holes 2B, are resin targets. In other feasible embodiments, all the positioning target through holes may be through hole targets. In still other feasible embodiments, all the positioning target through holes may be resin targets. A through hole target is formed, for example, by drilling a hole through the substrate layer 2 with a drilling machine, and a resin target is formed by drilling a through hole target with a drilling machine and filling the through hole target completely with resin. The diameter of each positioning target through hole may be, but is not limited to, 0.5-3 mm.
Step 2: A self-adhesive copper foil 20 is adhesively attached to the semi-finished circuit board 1 by vacuum pressing, or more specifically by a vacuum pressing and flattening machine, as shown in FIG. 2 and FIG. 3, wherein the self-adhesive copper foil 20 is in a wound state in the first place. Referring to FIG. 4, the self-adhesive copper foil 20 has a copper foil layer 21 and an insulating adhesive layer 22. The insulating adhesive layer 22 is applied over the copper foil layer 21. The substrate circuit layer 3 is in contact with the insulating adhesive layer 22 but not in contact with the copper foil layer 21. Before being adhesively attached to the semi-finished circuit board 1, the self-adhesive copper foil 20 may further include a protective film 23 adhesively attached to the side of the insulating adhesive layer 22 that faces away from the copper foil layer 21. The protective film 23 is used to prevent the insulating adhesive layer 22 from contamination or from sticking to other objects and, as shown in FIG. 3, is removed before the self-adhesive copper foil 20 is adhesively attached to the semi-finished circuit board 1. In step 2, the insulating adhesive layer 22 is in a semi-cured state (i.e., the B stage) and is dry to the touch, with the organic molecules in the insulating adhesive layer 22 having yet to be completely crosslinked.
Step 3: A plurality of copper foil target windows 211 are formed in the copper foil layer 21 as shown in FIG. 5. The copper foil target windows 211 correspond to the positioning target through holes 2A and 2B respectively in a thickness direction D, and each copper foil target window 211 has a larger contour than the corresponding positioning target through hole 2A or 2B. The difference in contour size should be sufficient to enable identification of the contours of the positioning target through holes 2A and 2B by machine vision. For example, the diameter of each copper foil target window 211 is at least 1.5 times the diameter of the corresponding positioning target through hole 2A or 2B.
Step 4: The portions of the insulating adhesive layer 22 that correspond to the copper foil target windows 211 respectively in the thickness direction D are removed to form a plurality of insulating adhesive target windows 221 that correspond to the positioning target through holes 2A and 2B respectively in the thickness direction D, as shown in FIG. 6. Each insulating adhesive target window 221 has a larger contour than the corresponding positioning target through hole 2A or 2B, and the contours of the insulating adhesive target windows 221 are generally identical to the contours of the copper foil target windows 211. Depending on the choice of manufacturing process, steps 3 and 4 may be performed by different methods. For example, the copper foil target windows 211 and the insulating adhesive target windows 221 may be sequentially formed in one drilling operation by a laser drilling machine, or the copper foil target windows 211 may be formed before the insulating adhesive target windows 221 are formed in a subsequent operation. Optionally, a thermal curing operation and/or a photocuring operation may be performed on the insulating adhesive layer 22 after the insulating adhesive target windows 221 are formed, in order to crosslink the insulating adhesive layer 22 completely.
Step 5: A first positioning operation is performed on the semi-finished circuit board 1, using at least some of the positioning target through holes 2A and 2B as the positioning reference points in a machine vision image. Generally, more than three positioning target through holes 2A and 2B are used as the positioning reference points to be identified in a machine vision image, so that the computation equipment employed can derive a circle from the positioning reference points and determine the position of the semi-finished circuit board 1 by way of the center of the circle. The first positioning operation may include the sub-step of: (1) moving the platform carrying the semi-finished circuit board 1 in order to align the semi-finished circuit board 1 with a machining machine; (2) moving the machining machine in order to align the machining machine with the semi-finished circuit board 1; or (3) moving the platform carrying the semi-finished circuit board 1 and the machining machine separately in order to align the machining machine and the semi-finished circuit board 1 with each other. After the first positioning operation, referring to FIG. 7 and FIG. 8, a plurality of windows 212 are formed in the copper foil layer 21, and the portions of the insulating adhesive layer 22 that correspond to the windows 212 respectively in the thickness direction are removed to form a plurality of vias 25 and thereby expose certain portions of the substrate circuit layer 3. The term “machining machine” refers to at least some of the equipment used in this step to form the windows 212, such as a laser drilling machine or an exposure machine for use in an exposure process. In some feasible embodiments, the windows 212 and the vias 25 are sequentially formed with a laser drilling machine.

Step 5 may be followed by plating the vias with copper and forming circuit patterns. The plating and patterning processes may differ, depending on the types of the positioning target through holes.

When the positioning target through holes are through hole targets (i.e., the positioning target through holes 2A in the drawings), step 5 may be followed by the following steps:
Step 6-1: An electrolessly plated copper layer 31 and an electroplated copper layer 32 are sequentially formed on the semi-finished circuit board 1 as shown in FIG. 9. The positioning target through holes 2A are through hole targets and therefore are not completely filled with the electrolessly plated copper layer 31 and the electroplated copper layer 32; the electrolessly plated copper layer 31 and the electroplated copper layer 32 are formed only on the hole walls of the positioning target through holes 2A. As the combined thickness of the electrolessly plated copper layer 31 and the electroplated copper layer 32 on the hole wall of each positioning target through hole 2A is generally less than 50 μm while the diameter of each positioning target through hole 2A is generally greater than 0.5 mm or even greater than 1 mm, the electrolessly plated copper layer 31 and the electroplated copper layer 32 on the hole wall of each positioning target through hole 2A have little effect on the contour of the positioning target through hole 2A and hence will not interfere with subsequent positioning by machine vision.
Step 7-1: A second positioning operation is performed on the semi-finished circuit board 1, using at least some of the partially filled positioning target through holes 2A as the positioning reference points in a machine vision image. The second positioning operation is similar to the first positioning operation and therefore will not be described in more detail. After the second positioning operation, the copper foil layer 21, the electrolessly plated copper layer 31, and the electroplated copper layer 32 are patterned to form a newly added circuit layer 4 as shown in FIG. 11. The circuits in the newly added circuit layer 4 are electrically connected to the circuits in the substrate circuit layer 3 by the electrolessly plated copper layer 31 and the electroplated copper layer 32 in the vias 25. The patterning process can be carried out by a conventional method that includes, for example but not limited to, applying a photomask, exposure to light, developing, alkali etching, and removing the photomask. During the patterning process, the electrolessly plated copper layer 31 and the electroplated copper layer 32 on the walls of the copper foil target windows 211, on the walls of the insulating adhesive target windows 221, and on the hole walls of the positioning target through holes 2A are also removed such that the original contours of the copper foil target windows 211, of the insulating adhesive target windows 221, and of the positioning target through holes 2A are restored.

When the positioning target through holes are resin targets (i.e., the positioning target through holes 2B in the drawings), step 5 may be followed by the following steps:
Step 6-2: An electrolessly plated copper layer 31 and an electroplated copper layer 32 are sequentially formed on the semi-finished circuit board 1 as shown in FIG. 9, such that the positioning target through holes 2B are covered with the electrolessly plated copper layer 31 and the electroplated copper layer 32.
Step 6-2-1: The electrolessly plated copper layer 31 and the electroplated copper layer 32 in the copper foil target windows 211 and in the insulating adhesive target windows 221 are removed (e.g., with a laser drilling machine or by a copper etching process) as shown in FIG. 10, thereby exposing the positioning target through holes 2B to facilitate subsequent positioning by machine vision.
Step 7-2: A second positioning operation is performed on the semi-finished circuit board 1, using at least some of the exposed positioning target through holes 2B as the positioning reference points in a machine vision image, as shown in FIG. 11. After the second positioning operation, the copper foil layer 21, the electrolessly plated copper layer 31, and the electroplated copper layer 32 are patterned to form a newly added circuit layer 4. The circuits in the newly added circuit layer 4 are electrically connected to the circuits in the substrate circuit layer 3 by the electrolessly plated copper layer 31 and the electroplated copper layer 32 in the vias 25.

Thus, the entire circuit board layer build-up process is completed. The vias and the newly added circuit layer are formed with the positional accuracy achieved by performing the first and the second positioning operations on the semi-finished circuit board 1 and are therefore highly precise in position. Afterward, referring to FIG. 12, a new layer build-up process can be performed by repeating the aforesaid steps sequentially, starting with step 1, in order to form the copper foil target windows and the insulating adhesive target windows again, allowing the positioning target through holes in the substrate layer 2 to serve as the positioning reference points in the machine vision images used for forming vias and another newly added circuit layer, thereby preventing layer errors, which have existed in the conventional circuit board layer build-up processes for a long time.

It should be pointed out that the semi-finished circuit board in the embodiment illustrated herein uses both through hole targets and resin targets for the sake of simplicity of description. Therefore, step 6-1 and step 6-2 are actually performed at the same time, and so are step 7-1 and step 7-2. In other feasible embodiments, the semi-finished circuit board may use only through hole targets or only resin targets, so either steps 6-1 and 7-1 or steps 6-2, 6-2-1, and 7-2 can be omitted. More specifically, steps 6-2, 6-2-1, and 7-2 are omitted when all the positioning target through holes of the semi-finished circuit board are through hole targets, and steps 6-1 and 7-1 are omitted when all the positioning target through holes of the semi-finished circuit board are resin targets.

What is claimed is:

1. A circuit board layer build-up process with enhanced positioning precision, comprising the following steps:
step 1: providing a semi-finished circuit board, wherein the semi-finished circuit board comprises a substrate layer and a substrate circuit layer, the substrate circuit layer is formed on the substrate layer, and the substrate layer has a plurality of positioning target through holes;
step 2: adhesively attaching a self-adhesive copper foil to the semi-finished circuit board by vacuum pressing, wherein the self-adhesive copper foil is initially in a wound state and has a copper foil layer and a semi-cured insulating adhesive layer, the insulating adhesive layer is applied on the copper foil layer, and the substrate circuit layer is in contact with the insulating adhesive layer but not in contact with the copper foil layer;
step 3: forming a plurality of copper foil target windows in the copper foil layer, wherein the copper foil target windows correspond to the positioning target through holes respectively in a thickness direction, and each of the copper foil target windows has a larger contour than a corresponding one of the positioning target through holes;
step 4: removing portions of the insulating adhesive layer that correspond to the copper foil target windows respectively in the thickness direction, thereby forming a plurality of insulating adhesive target windows corresponding to the positioning target through holes respectively in the thickness direction, wherein each of the insulating adhesive target windows has a larger contour than a corresponding one of the positioning target through holes; and
step 5: performing a first positioning operation on the semi-finished circuit board, with at least some of the positioning target through holes used as positioning reference points in a machine vision image, forming a plurality of windows in the copper foil layer after the first positioning operation, and forming a plurality of vias by removing portions of the insulating adhesive layer that correspond to the windows respectively in the thickness direction.

2. The circuit board layer build-up process of claim 1, further comprising the following steps to be performed after the step 5:
step 6-1: sequentially forming an electrolessly plated copper layer and an electroplated copper layer on the semi-finished circuit board, wherein at least some of the positioning target through holes are only partially filled with the electrolessly plated copper layer and the electroplated copper layer; and
step 7-1: performing a second positioning operation on the semi-finished circuit board, with at least some of the partially filled positioning target through holes used as positioning reference points in a machine vision image, and patterning the copper foil layer, the electrolessly plated copper layer, and the electroplated copper layer after the second positioning operation in order to form a newly added circuit layer, wherein the newly added circuit layer is electrically connected to the substrate circuit layer by the electrolessly plated copper layer and the electroplated copper layer in the vias.

3. The circuit board layer build-up process of claim 1, wherein in the step 1, at least some of the positioning target through holes are completely filled with resin, and the circuit board layer build-up process further comprises the following steps to be performed after the step 5:
step 6-2: sequentially forming an electrolessly plated copper layer and an electroplated copper layer on the semi-finished circuit board;
step 6-2-1: removing the electrolessly plated copper layer and the electroplated copper layer in each of the copper foil target windows and in each of the insulating adhesive target windows such that the positioning target through holes are exposed; and
step 7-2: performing a second positioning operation on the semi-finished circuit board, with at least some of the exposed positioning target through holes used as positioning reference points in a machine vision image, and patterning the copper foil layer, the electrolessly plated copper layer, and the electroplated copper layer after the second positioning operation in order to form a newly added circuit layer, wherein the newly added circuit layer is electrically connected to the substrate circuit layer by the electrolessly plated copper layer and the electroplated copper layer in the vias.
